(19) United States
(12) Patent Application Publication
(10) Pub. No.: US 2015/0372212 A1
(43) Pub. Date: Dec. 24, 2015

(54) TE-BASED THERMOELECTRIC MATERIAL HAVING COMPLEX CRYSTAL STRUCTURE BY ADDITION OF INTERSTITIAL DOPANT

(71) Applicant: Korea Electrotechnology Research Institute, Changwon-si (KR)

(72) Inventors: Su Dong Park, Changwon-si (KR); Bong Seo Kim, Changwon-si (KR); Bok Ki Min, Changwon-si (KR); Min Wook Oh, Changwon-si (KR); Jae Ki Lee, Changwon-si (KR); Hee Woong Lee, Changwon-si (KR); Gi Jeong Kong, Daejeon (KR)

(73) Assignee: Korea Electrotechnology Research Institute

(21) Appl. No.: 14/473,029

(22) Filed: Aug. 29, 2014

(30) Foreign Application Priority Data
Jun. 24, 2014 (KR) 10-2014-0077124

(51) Int. Cl. H01L 35/16; C30B 29/46; C30B 29/68

(52) U.S. Cl. CPC H01L 35/16; C30B 29/68; C30B 29/46

(57) ABSTRACT

This invention relates to a Te-based thermoelectric material having stacking faults by addition of an interstitial dopant, including unit cells configured such that A-B-A-C-A elements are stacked to five layers, in which A element of a terminal of a unit cell and A element of a terminal of another unit cell are repeatedly stacked by a van der Waals interaction, wherein an interstitial element as the dopant is located at an interstitial position between the repeatedly stacked A elements adjacent to each other, thus generating stacking faults of the repeatedly stacked unit cells to thereby form a twin as well as a complex crystal structure different from the unit cells (where A is Te or Se, B is Bi or Sb, and C is Bi or Sb).

### REFERENCE TO RELATED APPLICATIONS

This application claims the priority benefit of Korean Patent Application No. 10-2014-00771 24 filed on Jun. 24, 2014, the entire contents of which are incorporated herein by reference.

### FIELD OF THE INVENTION

The present invention relates to a Te-based thermoelectric material having a complex crystal structure by addition of an interstitial dopant, and more particularly, to a Te-based thermoelectric material having a complex crystal structure by addition of an interstitial dopant, wherein a Te-based thermoelectric material is added with an interstitial dopant such as Ag, so that the dopant is located at an interstitial position, thus breaking lattice stacking of the thermoelectric material to thereby form a new complex crystal structure due to stacking faults, ultimately improving thermoelectric performance.

### BACKGROUND OF THE INVENTION

Typically, a thermoelectric material for use in thermoelectric power generation and thermoelectric cooling is responsible for increasing performance of a thermoelectric device with an enhancement in thermoelectric properties. The thermoelectric performance is determined by properties such as thermoelectromotive force (V), Seebeck coefficient (a), Peltier coefficient (π), Thomson coefficient (τ), Nernst coefficient (Q), Ettingshausen coefficient (P), electrical conductivity (σ), power factor (PF), performance index (Z), dimensionless performance index (ZT=α²σT/K (wherein T is an absolute temperature)), thermal conductivity (κ), Lorenz number (L), and electrical resistivity (ρ).

In particular, dimensionless performance index (ZT) is an important factor which determines thermoelectric conversion energy efficiency. When a thermoelectric device is manufactured using a thermoelectric material having a high performance index (Z=α²σ/κ), cooling and power generation efficiency may increase.

Currently commercially available thermoelectric materials have a ZT of about 1, among which an AgPbₘSbTeₘ₊₂ alloy is known to have ZT=1.7 (at 700K) and thus exhibits very good thermoelectric properties.

An AgPbₘSbTeₘ₊₂ alloy, which has a cubic crystal structure, is configured such that Pb and Te are arranged to cross each other, and Ag and Sb are positioned in place of Pb. However, such a conventional thermoelectric material has poor thermoelectric performance and thus limitations are imposed on the application thereof to fields that require high precision.

To solve the problems, Korean Patent Application Publication No. 10-2011-0079490 (Laid-open date: Jul. 7, 2011) discloses “Method of preparing Te-based thermoelectric material having twin by addition of dopant and thermoelectric material thereby”. This method includes 1) weighing components of a Te-based thermoelectric material and a dopant added thereto so as to be adapted for a component ratio and melting the components in an ampoule in a vacuum in a furnace; 2) thermally treating the melted components under the condition that only a temperature is lowered and then quenching them, thus producing an ingot; and 3) grinding the ingot and then performing hot pressing and wire cutting, wherein the dopant has an ionic radius of 56-143 pm.

In addition, Korean Patent Application Publication No. 10-2013-0078478 (Laid-open date: Jul. 10, 2013) discloses “Method of preparing Te-based thermoelectric material having twin by addition of dopant and sintering of nanoparticles”.

This method includes 1) weighing components of a Te-based thermoelectric material and a dopant added thereto so as to be adapted for a component ratio and melting the components in an ampoule in a vacuum in a furnace; 2) quenching the melted components into an ingot; 3) grinding the ingot thus obtaining component nanoparticles; 4) subjecting the component nanoparticles to spark plasma sintering for 1-20 min to form a sintered product; and 5) wire-cutting the sintered product.

In the existing techniques as above, the materials added as the dopant are replaced with the specific atom of the Te-based thermoelectric material, thus changing the crystal structure and forming a twin, and thereby thermoelectric performance such as dimensionless performance index may be enhanced. However, because the degree of changes in the crystal structure is not high, an enhancement in the thermoelectric performance may become insignificant.

### SUMMARY OF THE INVENTION

Accordingly, the present invention has been made keeping in mind the problems encountered in the prior art, and an object of the present invention is to provide a Te-based thermoelectric material having a complex crystal structure by addition of an interstitial dopant, wherein a Te-based thermoelectric material may be added with an interstitial dopant such as Ag, so that the dopant may be located at an interstitial position, thus breaking lattice stacking of the thermoelectric material to thereby form a new complex crystal structure due to stacking faults, ultimately improving thermoelectric performance.

In order to accomplish the above object, the present invention provides a Te-based thermoelectric material having a complex crystal structure by addition of an interstitial dopant, comprising unit cells configured such that A-B-A-C-A elements are stacked to five layers, in which A element of a terminal of a unit cell and A element of a terminal of another unit cell are repeatedly stacked by a van der Waals interaction, wherein an interstitial element as the dopant is located at an interstitial position between the repeatedly stacked A elements adjacent to each other, thus generating stacking faults of the repeatedly stacked unit cells to thereby form a twin as well as a complex crystal structure different from the unit cells (where A is Te or Se, B is Bi or Sb, and C is Bi or Sb).

The Te-based thermoelectric material preferably comprises any one selected from among Bi_{0.5}Sb_{1.5}Te₃, Bi₂Te₃, Sb₂Te₃ and Bi₂Se₃, or a mixture of two or more thereof.

The complex crystal structure is preferably a Bi₁₃Te₂₀ structure.

The dopant is preferably any one selected from among Na, K, Zn, Al, Ti, V, Cr, Mn, Fe, Co, Ni, Cu, Pd, Ag, Pt, Au and Hg, or a mixture of two or more thereof.

The dopant is preferably added in an amount of 0.01 to 1 wt % based on the Te-based thermoelectric material.

According to the present invention, a Te-based thermoelectric material is added with an interstitial dopant such as Ag, so that the dopant is located at an interstitial position, thus breaking lattice stacking of the thermoelectric material to thereby form a new complex crystal structure due to stacking faults, ultimately improving thermoelectric performance.

### BRIEF DESCRIPTION OF THE DRAWINGS

The patent or application file contains at least one drawing executed in color. Copies of this patent or patent application publication with color drawings will be provided by the Office upon request and payment of the necessary fee.

The above and other objects, features and advantages of the present invention will be more clearly understood from the following detailed description taken in conjunction with the accompanying drawings, in which:

FIG. 1 illustrates a crystal structure of Bi₂Te₃ which is a Te-based thermoelectric material according to an embodiment of the present invention;

FIG. 2 schematically illustrates a crystal structure of Bi₂Te₃ which is the Te-based thermoelectric material according to the embodiment of the present invention;

FIG. 3 schematically illustrates a crystal structure of Bi₁₃Te₂₀ where Ag is located at an interstitial position according to an embodiment of the present invention; and

FIG. 4 illustrates a thermoelectric material doped with 0.01 wt % of Ag according to an embodiment of the present invention, wherein (a) a scanning electron microscope image, (b) a magnified image, (c) an HRTEM image, and (d) a schematic view of a twin boundary and a lattice stacking structure corresponding thereto.

### DETAILED DESCRIPTION OF THE INVENTION

Hereinafter, a detailed description will be given of preferred embodiments of the present invention with reference to the appended drawings.

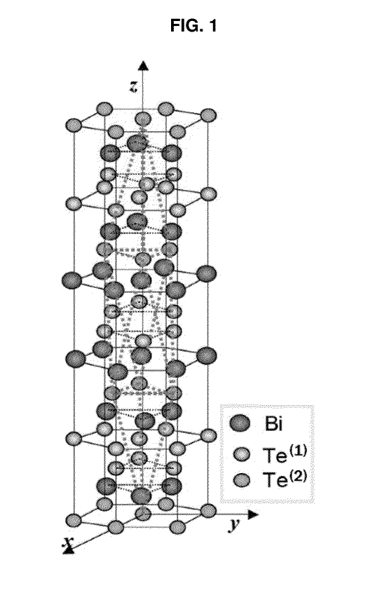

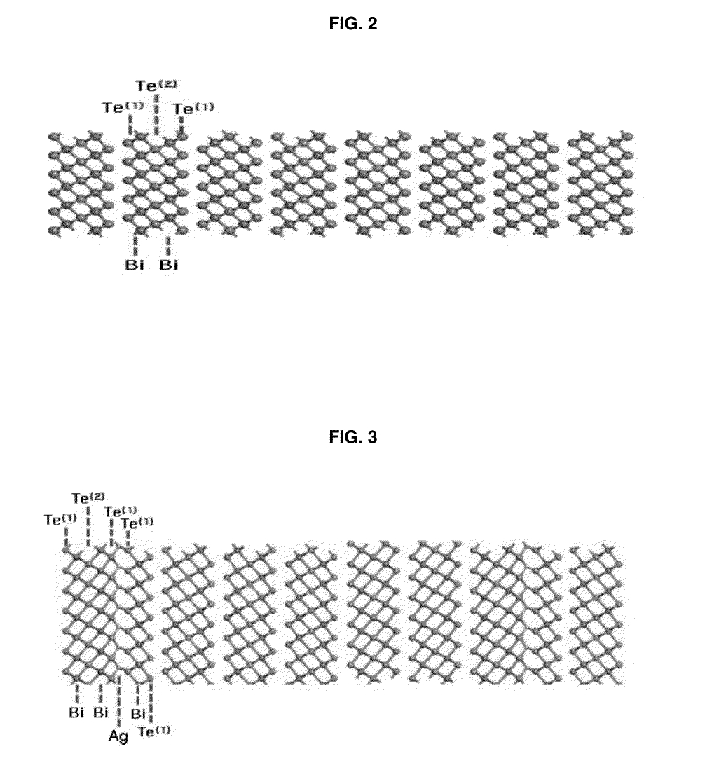

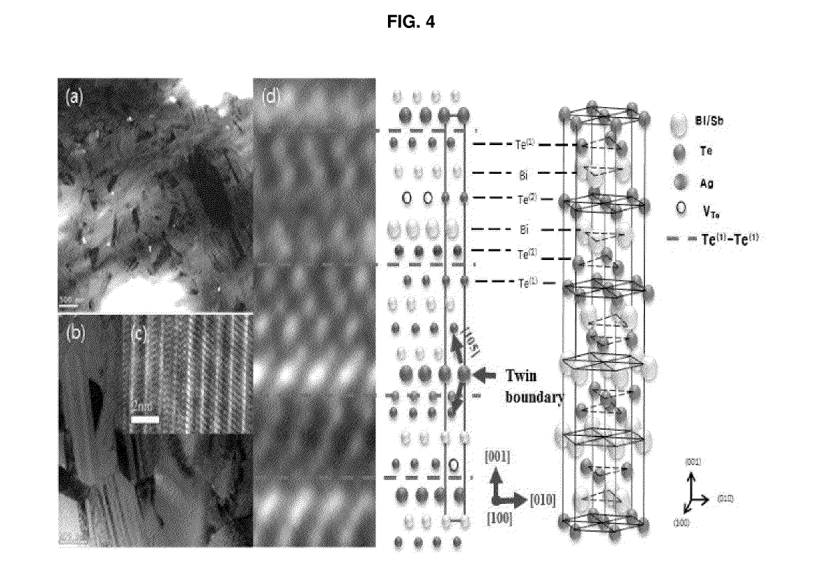

FIG. 1 illustrates a crystal structure of Bi₂Te₃ which is a Te-based thermoelectric material according to an embodiment of the present invention, FIG. 2 schematically illustrates a crystal structure of Bi₂Te₃ which is the Te-based thermoelectric material according to the embodiment of the present invention, FIG. 3 schematically illustrates a crystal structure of Bi₁₃Te₂₀ where Ag is located at an interstitial position according to an embodiment of the present invention, and FIG. 4 illustrates a thermoelectric material doped with 0.01 wt % of Ag according to an embodiment of the present invention, wherein (a) a scanning microscope image, (b) a magnified image, (c) an HRTEM image, and (d) a schematic view of a twin boundary and a lattice stacking structure corresponding thereto.

As illustrated in FIGS. 1 and 2, Bi₂Te₃, which is a Te-based thermoelectric material, has a repeated structure of five layers of Te⁽¹⁾—Bi—Te⁽²⁾—Bi—Te⁽¹⁾.

This structure is configured such that Te⁽¹⁾ layers at both ends and newly repeated five layers at boundaries thereof form van der Waals interactions.

Briefly in the repeated structure of five layers such as Te⁽¹⁾—Bi—Te⁽²⁾—Bi—Te⁽¹⁾/Te⁽¹⁾—Bi—Te⁽²⁾—Bi—Te⁽¹⁾, Te⁽¹⁾/Te⁽¹⁾ may form a van der Waals interaction.

In the present invention, the Bi₂Te₃ thermoelectric material having a repeated structure of five layers such as Te⁽¹⁾—Bi—Te⁽²⁾—Bi—Te⁽¹⁾/Te⁽¹⁾—Bi—Te⁽²⁾—Bi—Te⁽¹⁾ is added with a dopant, so that the element added as the dopant is located at the interstitial position between the Te⁽¹⁾/Te⁽¹⁾ layers, thereby breaking typical lattice stacking of the Bi₂Te₃ structure to thus generate stacking faults, resulting in a new complex crystal structure.

In an embodiment of the present invention, Ag is added as the dopant. As illustrated in FIG. 3, the addition of the dopant results in that the element Ag is located at the interstitial position between the Te⁽¹⁾/Te⁽¹⁾ layers, and thus the repeated layer structure such as /Te—Bi—Te—Bi—Te/Te—Bi—Te—Bi—Te/ may break, giving a Bi₁₃Te₂₀ material having a new lattice structure configured such that five layers and three layers are mixed at both sides of Ag, such as Te—Bi—Te—Bi—Te/Ag/Te—Bi—Te/. This structure is confirmed to be formed by mixing a BiTe₂ layer while forming a twin in the unit lattice due to stacking faults.

In order to identify stacking faults by addition of an interstitial dopant in the present invention, a test sample is manufactured and the structure thereof is observed. Specifically, a Bi₂Te₃ thermoelectric material is formed as a Te-based thermoelectric material having a high purity of 99.999% or more.

Then, the thermoelectric material and a dopant Ag are washed using hydrochloric acid, nitric acid, acetone or ethanol, and individual components are weighed at a predetermined component ratio using a precision balance. The dopant Ag is preferably added in an amount of 0.01 to 1 wt % based on the Te-based thermoelectric material Bi₂Te₃. If the amount thereof is less than 0.01 wt %, there are almost no addition effects. In contrast, if the amount thereof exceeds 1 wt %, the thermoelectric efficiency may become poor due to an excessive doping level.

In an embodiment of the present invention, a test sample comprising Bi₂Te₃ doped with Ag in an amount of 0.1 wt % based thereon is manufactured. The weighed components are placed in a quartz tube ampoule, and the inner pressure of the ampoule is set to 10⁻⁵ torr, and the ampoule is filled with Ar gas and sealed.

The sealed ampoule is placed in a furnace, melted at about 960° C. for 10 hr and then quenched. The ingot formed by quenching is ground into nanoparticles, which are then subjected to a spark plasma process at 420° C. for 10 min at 50 MPa, followed by wire cutting, thus yielding a thermoelectric material sample having a predetermined size.

This sample is observed in terms of a scanning electron microscope image and a structure corresponding thereto. FIG. 4 illustrates the structure configured such that five layers and three layers are mixed at both sides of Ag, such as Te—Bi—Te—Bi—Te/Ag/Te—Bi—Te/. Thereby, it can be seen to form a material having a new complex crystal structure BTNS (Bi₁₃Te₂₀) including six Bi₂Te₃ layers and a BiTe₂ layer mixed together, in which the element Ag is present in interstitial form.

As the dopant element is present in interstitial form as above, it is understood that a new complex crystal structure different from the original crystal structure is easily formed in the Te-based thermoelectric material.

Based on the experimental results as above, the calculation of electron structure for theoretical verification was performed. The results are shown in Table 1 below.

TABLE 1

| | | E_{dop} (eV) | |
|---|---|---|---|
| E_{dop} (eV) | E_{interface} (mJ/m²⁾ | Pristine | Twin |
| BT (undoped) | 44.1 | | |
| Ag_{int.} | −60.1 | −0.33 | −0.43 |
| Ag_{sub.Bi/Sb} | 191 | −0.11 | 0.04 |
| Ag_{sub.Te1} | 225 | 0.21 | 0.4 |
| Ag_{sub.Te2} | 76.8 | 0.76 | 0.8 |
| BTNS | 74.4 | | |
| Ag_{sub.Bi}(NS) | 192.9 | −0.49 | −0.38 |
| Ag_{int.}(NS) | −21.67 | −0.68 | −0.77 |

As is apparent from Table 1, when a typical Bi₂Te₃ structure is doped with Ag, Ag is present in interstitial form between the Te⁽¹⁾⁻Te⁽¹⁾ layers, thus exhibiting the lowest twin formation energy.

Based on the calculation results using the typical Bi₂Te₃ crystal structure as illustrated in FIG. 2, interstitial Ag showed n-type conductivity and the lattice constant increased in a c-axis direction.

As illustrated in FIG. 3, in a new crystal structure model (=Bi₁₃Te₂₀=BTNS) including six Bi₂Te₃ layers and a BiTe₂ layer, interstitial Ag for forming a twin had an energetically stable structure.

In Table 1, Agᵢₙₜ indicates Ag which is present in interstitial form, and Ag_{sub} indicates Ag which is substituted at a specific element position. For Agᵢₙₜ, the energy value becomes significantly negative. This means that it has a low energy state and that such an interstitial structure is stable, which agrees with experimental results.

When the Te-based thermoelectric material is added with the dopant in this way, the dopant is present in interstitial form, thus forming a twin while causing stacking faults of the lattice, thereby increasing thermoelectric performance of the thermoelectric material.

As described hereinbefore, the present invention provides a Te-based thermoelectric material having a complex crystal structure by addition of an interstitial dopant. According to the present invention, a Te-based thermoelectric material is added with an interstitial dopant such as Ag, so that the dopant is located at an interstitial position, thus breaking lattice stacking of the thermoelectric material to thereby form a new complex crystal structure due to stacking faults, ultimately enhancing thermoelectric performance.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A Te-based thermoelectric material having a complex crystal structure by addition of an interstitial dopant, comprising unit cells configured such that A-B-A-C-A elements are stacked to five layers, in which A element of a terminal of a unit cell and A element of a terminal of another unit cell are repeatedly stacked by a van der Waals interaction,
wherein an interstitial element as the dopant is located at an interstitial position between the repeatedly stacked A elements adjacent to each other, thus generating stacking faults of the repeatedly stacked unit cells to thereby form a complex crystal structure different from the unit cells (where A is Te or Se, B is Bi or Sb, and C is Bi or Sb).

2. The Te-based thermoelectric material of claim 1, wherein the Te-based thermoelectric material comprises any one selected from among Bi_{0.5}Sb_{1.5}Te₃, Bi₂Te₃, Sb₂Te₃, and Bi₂Se₃, or a mixture of two or more thereof.

3. The Te-based thermoelectric material of claim 1, wherein the complex crystal structure is a Bi₁₃Te₂₀ structure.

4. The Te-based thermoelectric material of claim 1, wherein the dopant is any one selected from among Na, K, Zn, Al, Ti, V, Cr, Mn, Fe, Co, Ni, Cu, Pd, Ag, Pt, Au and Hg, or a mixture of two or more thereof.

5. The Te-based thermoelectric material of claim 1, wherein the dopant is added in an amount of 0.01 to 1 wt % based on the Te-based thermoelectric material.

6. The Te-based thermoelectric material of claim 1, wherein the complex crystal structure has a twin.
